(19) United States
(12) Patent Application Publication
(10) Pub. No.: US 2024/0355579 A1
(43) Pub. Date: Oct. 24, 2024

(54) HEIGHT SENSING SYSTEM FOR ELECTRON BEAM METROLOGY TOOL

(71) Applicant: KLA Corporation, Milpitas, CA (US)

(72) Inventors: Yeishin Tung, San Jose, CA (US); Peter Lin, Shanghai (CN); Mi Zhang, Shanghai (CN); Chengping Zhang, Shanghai (CN); Sameet Shriyan, Milpitas, CA (US)

(21) Appl. No.: 18/138,709

(22) Filed: Apr. 24, 2023

(51) Int. Cl. H01J 37/22; G01B 11/14; H01J 37/20

(52) U.S. Cl. CPC H01J 37/226; G01B 11/14; H01J 37/20

(57) ABSTRACT

A beam of light is directed at a workpiece on a stage. The workpiece is disposed an absolute distance from an electron beam column. The beam of light that is reflected off the workpiece is received at a sensor. Using the beam of light, a nominal distance between the electron beam column and the workpiece on the stage is determined.

### FIELD OF THE DISCLOSURE

This disclosure relates to metrology systems for semiconductor wafers.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s). Many metrology processes are performed using an electron beam tool.

The absolute distance between an electron beam column in a metrology tool and a workpiece on the stage of the metrology tool is used to provide a desired focus. Previously, a metallic L-shaped target was machined on the workpiece to enable mechanical alignment in the X, Y, and Z directions. The L-shaped target would form a cross. A uniform cross would enable alignment in the X and Y directions. The Z direction alignment, such as an absolute distance, can involve finding the best focus position. Best focus can be determined by finding where the image of the workpiece has a sharpest edge and/or a highest contrast. The L-shaped target can have roughness, scratches, non-uniformities, or deposits because it is machined. Determining the focus alignment can be difficult because of these imperfections in the L-shaped target.

Due to tooling machine limitation, large feature sizes cannot provide enough pattern complexities to have a full measurement and/or evaluation of optical performance. Additionally, the machined metal trenches are rough, which can cause scattering that negatively affects the measurements. Furthermore, the target may not be on the same height as workpiece, which affects the alignment accuracy. The can affect the performance of the height sensor.

New systems and techniques are needed.

### BRIEF SUMMARY OF THE DISCLOSURE

A system is provided in a first embodiment. The system includes a stage configured to hold a workpiece; an electron beam column configured to direct an electron beam at the workpiece on the stage; a light source configured to generate a light beam at the workpiece on the stage; a sensor configured to receive the light beam reflected from the workpiece; a mirror configured to reflect the light beam received from the workpiece toward the sensor; and a processor in electronic communication with the sensor. The processor is configured to use measurements from the sensor to determine a displacement from a nominal distance between the electron beam column and the workpiece on the stage.

The system can include a second mirror and a third mirror. The second mirror and the third mirror are positioned in a path of the light beam. The second mirror is positioned to direct the light beam from the light source at the workpiece. The third mirror is positioned to direct the light beam from the workpiece at the mirror. The second mirror and the third mirror can each be a fold mirror.

The system can further include plano-convex lenses disposed in the path of the light beam between the second mirror and the workpiece.

The system can include a beam splitter positioned in a path of the light beam between the workpiece and the light source. The beam splitter directs at least some of the light beam at the sensor.

The light source can be a light-emitting diode.

The system can include a convex lens in a path of the light beam between the light source and the workpiece.

The system can include a slit in a path of the light beam between the light source and

the workpiece.

The mirror may be a spherical mirror.

The workpiece may be a semiconductor wafer.

A method is provided in a second embodiment. The method includes directing a beam of light from a light source at a workpiece on a stage. The workpiece is disposed an absolute distance from an electron beam column. The beam of light is reflected off the workpiece. The beam of light that was reflected off the workpiece is received at a sensor. Using a processor, a displacement from a nominal distance between the electron beam column and the workpiece on the stage is determined.

The workpiece may be a semiconductor wafer.

The method can include reflecting the beam of light reflected off the workpiece using a mirror. Reflecting the beam of light off the workpiece directs the beam of light to the mirror.

The directing can include reflecting the beam of light off a second mirror disposed in a path of the beam of light between the light source and the workpiece.

Reflecting the beam of light off the workpiece can include reflecting the beam of light off a third mirror disposed in the path of the beam of light between the workpiece and the mirror.

The method can include splitting the beam of light reflected off the workpiece using a beam splitter. Some of the light beam is directed by the beam splitter to the sensor.

The directing can include focusing the beam of light.

The method can include directing the beam of light reflected off the workpiece at a same point on the workpiece a second time before the beam of light is received at the sensor.

The method can include adjusting a height of a stage based on the displacement from the nominal distance.

### DESCRIPTION OF THE DRAWINGS

For a fuller understanding of the nature and objects of the disclosure, reference should be made to the following detailed description taken in conjunction with the accompanying drawings, in which:

FIG. 1 is a block diagram of an embodiment of a system in accordance with the present disclosure;

FIG. 2 is a block diagram of the optics used in the system of FIG. 1;

FIG. 3 shows exemplary test results using the system of FIG. 1;

FIG. 4 illustrates a double pass using an embodiment of the system of FIG. 1 compared to a single pass; and

FIG. 5 shows a calibration technique for the system of FIG. 1.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

A height sensing system can measure a displacement from a nominal distance between the electron beam column and the workpiece on the stage of a metrology tool. For example, the absolute distance can be between a top surface of the workpiece on the stage and a lowermost surface of an objective lens in the electron beam column. A particular metrology application may have a nominal distance (which can be the absolute distance, a point along the absolute distance, or a range within the absolute distance) between the electron beam column and the workpiece on the stage of a metrology tool to provide a desired electron beam focus. The height sensing system can be used during workpiece scanning to verify that the electron beam column is positioned at this nominal height relative to the workpiece. This can occur during measurement setup or during other periods of metrology tool operation.

The absolute distance can be affected by structures on the workpiece, the shape of the workpiece (e.g., bow, thickness changes, etc.), changes in the height of the stage, and/or incorrect movement of the stage (e.g., too much or too little movement). These differences also can affect the placement of the nominal distance.

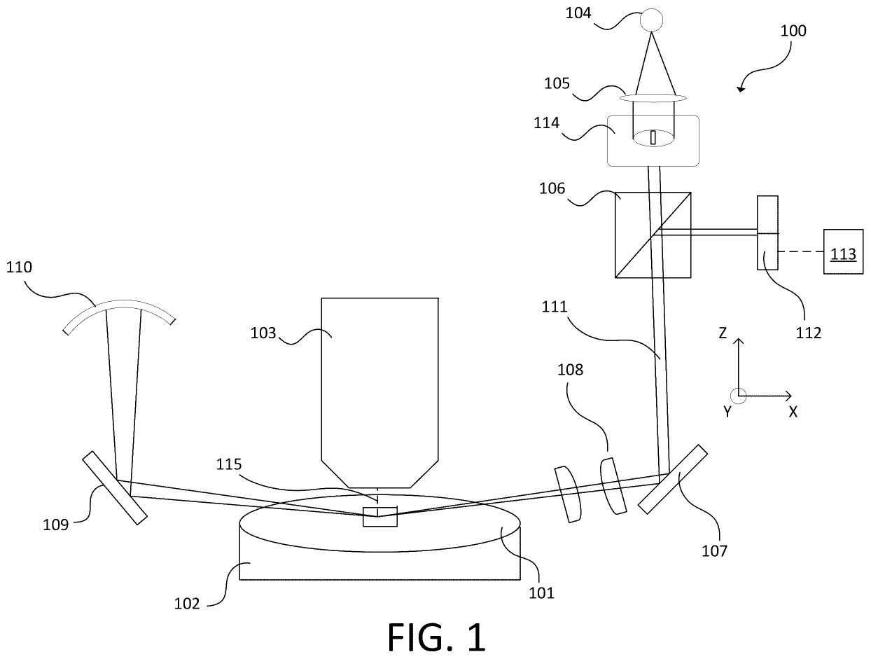

FIG. 1 is a block diagram of a system 100. The system 100 can be part of a metrology tool. The system 100 includes a stage 102 configured to hold a workpiece 101. The workpiece 101 can be a semiconductor wafer, a Calchip, or another type of substrate. The stage 102 can move in the X, Y, and Z directions using an actuator. The system 100 also includes an electron beam column 103 configured to direct an electron beam at the workpiece 101 on the stage 102. The distance between the end of the electron beam column 103 and a top surface of the workpiece 101 is the absolute distance in FIG. 1 (shown with dotted line 115).

A light source 104 is configured to generate a light beam 111 at the workpiece 101 on the stage 102. The light source can be a light-emitting diode (LED) or a laser. The light beam 111 can use visible light. For example, the light beam 111 can predominantly use red wavelengths of light. The spot on the workpiece 101 formed by the light beam 111 can vary. For example, the spot on the workpiece 101 may be 2 mm diameter or 2 mm by 2 mm square.

The light beam 111 can have a grazing angle of incidence on the workpiece 101. This can avoid many of the mechanical components in the system 100 and can provide high reflectivity. For example, the light beam 111 can have an angle of incidence of 3.5±0.5 degrees with respect to a planar surface of the workpiece 101.

A sensor 112 is configured to receive the light beam 111 reflected from the workpiece 101. The sensor 112 can be a bicell photodiode that is connected to or part of a printed circuit board (PCB). The bicell photodiode can read if the imaging signal is in the upper half or lower half of the bicell photodiode. Height adjustment of the stage 102 can be based on the position of the imaging signal on the sensor 112.

A mirror 110 can be configured to reflect the light beam received from the workpiece 101 toward the sensor 112. The mirror 110 can be a spherical mirror, though other mirrors can perform this function. For example, light reflected from the workpiece 101 can be reflected back at the workpiece 101 using the mirror 110. This reflected light can then be directed toward the sensor 112 after it is reflected by the workpiece 101.

A processor 113 is in electronic communication with the sensor 112. The processor 113 also can be in electronic communication with the stage 102 actuator or other components in the system 100. The processor 113 can use measurements from the sensor 112 to determine a relative displacement from nominal distance. The nominal distance can be determined for a best electron beam focus on the workpiece 101. The processor 113 also can determine adjustments to the stage 102 in the Z direction to enable a desired focus position and/or placement of the workpiece 101 within the nominal distance.

The processor 113 typically comprises a programmable processor, which is programmed in software and/or firmware to carry out the functions that are described herein, along with suitable digital and/or analog interfaces for connection to the other elements of system 100. Alternatively or additionally, the processor 113 comprises hard-wired and/or programmable hardware logic circuits, which carry out at least some of the functions of the processor 113. Although the processor 113 is shown in FIG. 1, for the sake of simplicity, as a single, monolithic functional block, in practice the processor 113 may comprise multiple, interconnected control units, with suitable interfaces for receiving and outputting the signals that are illustrated in the figures and are described in the text. Program code or instructions for the processor 113 to implement various methods and functions disclosed herein may be stored in readable storage media, such as a memory in the processor 113 or other memory.

The focal length of the electron beam column 103 can be fixed. Instead of changing focus of each optical component in the electron beam column 103, the workpiece 101 can be brought toward or away from the fixed focal plane (i.e., can move in the Z direction) using an actuator associated with the stage 102. While a Z height sensor for the stage 102 can monitor the height of the stage 102, it can be difficult to know if the Z height sensor alone moved the stage 102 to the best focus position in the Z direction. Different workpieces 101 can have a different heights and a single workpiece 101 can have height differences across the workpiece 101.

The system 100 can include a second mirror 107 and a third mirror 109. The second mirror 107 and third mirror 109 can be fold mirrors, though other mirrors or optical components that perform this function can be used. For example, the second mirror 107 and/or third mirror 109 also can be a penta prism. The second mirror 107 and third mirror 109 can be positioned in a path of the light beam 111 such that the second mirror 107 directs the light beam 111 from the light source 104 at the workpiece 101 and the third mirror 109 directs the light beam 111 from the workpiece 101 to the mirror 110. The second mirror 107 and third mirror 109 also can receive reflected light in the opposite direction of the path of the light beam 111.

The system can include compound lenses 108 disposed in the path of the light beam 111 between the second mirror 107 and the workpiece 101. Two lenses are illustrated as part of the compound lenses 108, but more or fewer lenses can be used. The compound lenses 108 focus the light beam 111 onto the workpiece 101. In an instance, the compound lenses 108 are plano-convex lenses. An additional set of compound lenses also can be positioned between the second mirror 107 and the beam splitter 106.

A beam splitter 106 can be positioned in the path of the light beam 111 between the workpiece 101 and the light source 104. The beam splitter 106 can direct at least some of the light beam 111 at the sensor 112. For example, the beam splitter 106 can be in the path of the light beam 111 between the light source 104 and the second mirror 107.

The system can include a convex lens 105 in the path of the light beam 111 between the light source 104 and the workpiece 101. For example, the convex lens 105 can be in the path of the light beam 111 between the light source 104 and the beam splitter 106. The convex lens 105 can collimate the light beam 111. While one convex lens 105 is illustrated, a set of lenses also can be used. The convex lens 105 may be part of a Kohler illumination system.

A slit 114 can be positioned in the path of the light beam 111 between the light source 104 and the workpiece 101. For example, the slit 114 can be in the path of the light beam 111 between the light source 104 and the beam splitter 106, such as downstream from the convex lens 105. In an instance, the slit 114 has a dimension of 2*0.12 mm. The slit 114 can be fixed or can be adjustable.

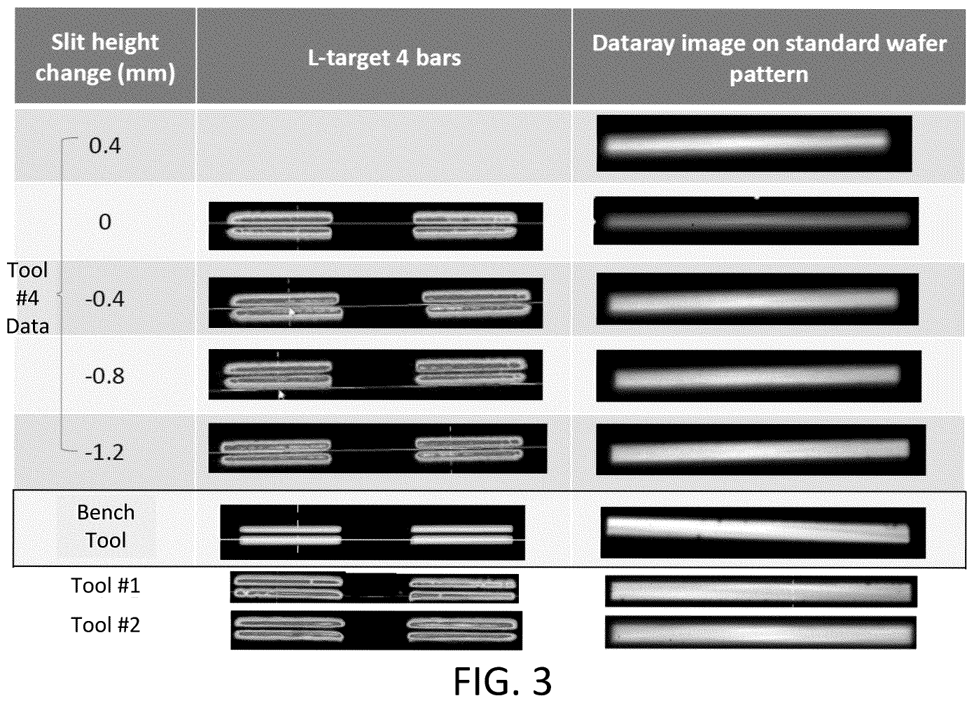

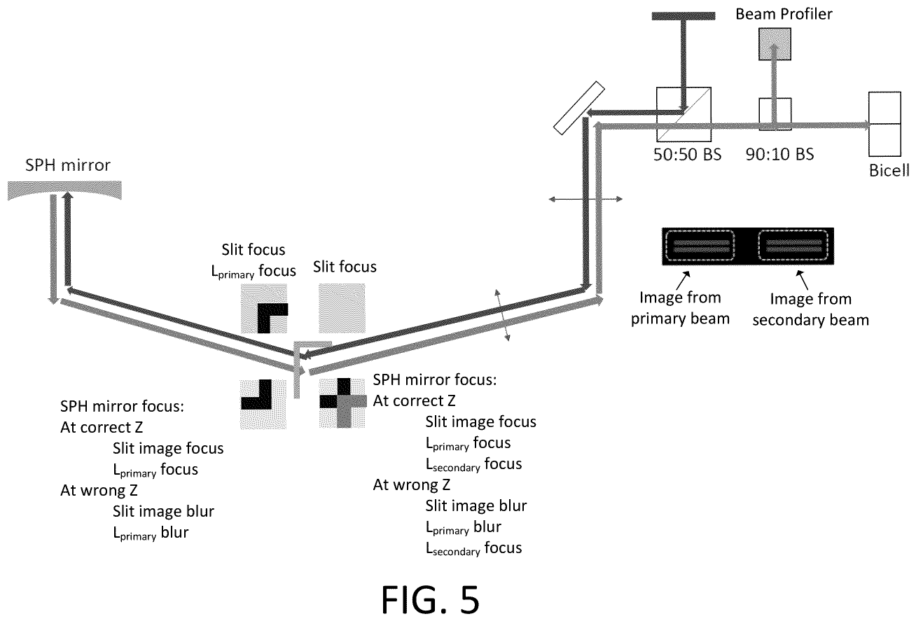

Pattern effect can be controlled in the system 100 by adjusting the illumination uniformity of the light source 104, the slit focus of the slit 114, the spherical mirror focus of the mirror 110, or the paracentricity of the primary and secondary beams. This can be seen in the illustration shown in FIG. 5. FIG. 5 shows the L-shaped target on the workpiece. The beam profiler in FIG. 5 can collect the alignment images, such as those illustrated in FIG. 3 and FIG. 5.

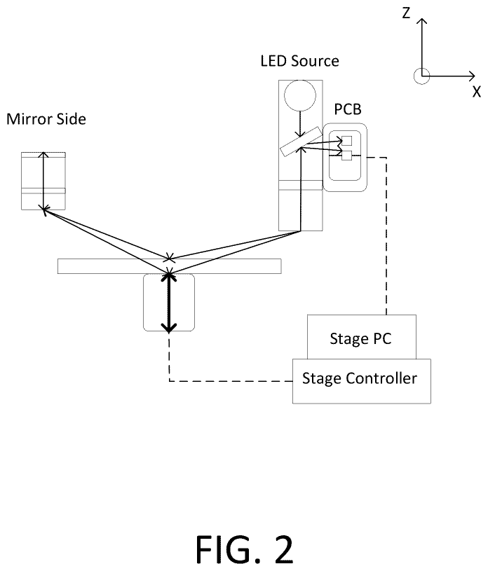

FIG. 2 is a block diagram of the optics used in the system 100 of FIG. 1. The stage controller can move the stage in the Z direction. The stage controller can include an actuator that can move the stage in at least the Z direction. The stage controller can be in electronic communication with a processor (“Stage PC”), which can be the same or different from the processor 113 in FIG. 1. In an instance, the stage controller is part of the processor 113. In another instance, the stage controller is an additional processor in electronic communication with the processor 113.

During operation of the embodiment in FIG. 2, a beam of light (i.e., a light beam) from a light source is directed at a workpiece on the stage. As shown in FIG. 1, the workpiece is positioned an absolute distance from an electron beam column. Turning back to FIG. 2, the beam of light is reflected off the workpiece and is received at a sensor. If a position of the workpiece is not nominal then the bicell photodioide generates a voltage difference for stage 102 feedback control.

Using a processor, a relative displacement from nominal distance can be determined. The nominal distance can be determined for a best electron beam focus on the workpiece. The system can then be aligned to this specific height.

The absolute distance from the electron beam column and the workpiece on the stage also can be determined. A signal difference can mean that the absolute distance is outside of specifications.

For example, as shown in FIG. 2, light from the light beam imaging the top of the bicell photodiode in the PCB or the bottom of the bicell photodiode in the PCB means that the absolute distance or displacement from nominal distance is outside of specifications. The height of the stage can be adjusted in the Z direction to bring the absolute distance or displacement within specifications. The stage height can be adjusted to accommodate different workpiece heights, different wafer curvatures, or different chuck designs.

The beam of light reflected off the workpiece can be further reflected using a mirror. Reflecting the beam of light off the workpiece can direct the beam of light to the mirror.

The beam of light can be reflected off a second mirror disposed in a path of the beam of light between the light source and the workpiece. The beam of light reflected off the workpiece can be reflected off a third mirror in the path of the beam of light between the workpiece and the mirror.

The beam of light reflected off the workpiece can be split using a beam splitter. At least some of the light beam is directed by the beam splitter to the sensor.

The beam of light can be focused as it is transmitted along its path.

Collecting height sensor tooling camera images of patterns on the wafer can be used to perform position alignment and focus alignment. For example, the streets between dies on the workpiece can be used to align in the X direction and Y direction. Geometric patterns can be used to adjust focus or field tilt.

FIG. 3 shows exemplary test results using the system 100. FIG. 3 is used to determine height sensor conjugate reference during alignment process. The slit height change is shown for Tool #4, which can include an embodiment of system 100. This is compared against a bench tool and two other tools with an embodiment of the system 100 (Tool #1 and Tool #2). The image on the left is the L target. The image on the right is a corresponding wafer image at different conjugate positions for the various tools.

As shown in FIG. 3, Tool #1 has a sharp outer edge compared to the standard wafer result with good pattern effect (PE). There is an image quality difference between the L target and the wafer.

As slit height is changed on Tool #4, the dataray image becomes sharper. Eventually the RS patterns can be seen. The pattern effect was reduced by approximately 450 nm as the slit height changed from 0.4 mm to −1.2 mm. This change resulted in a pattern effect of 240 nm.

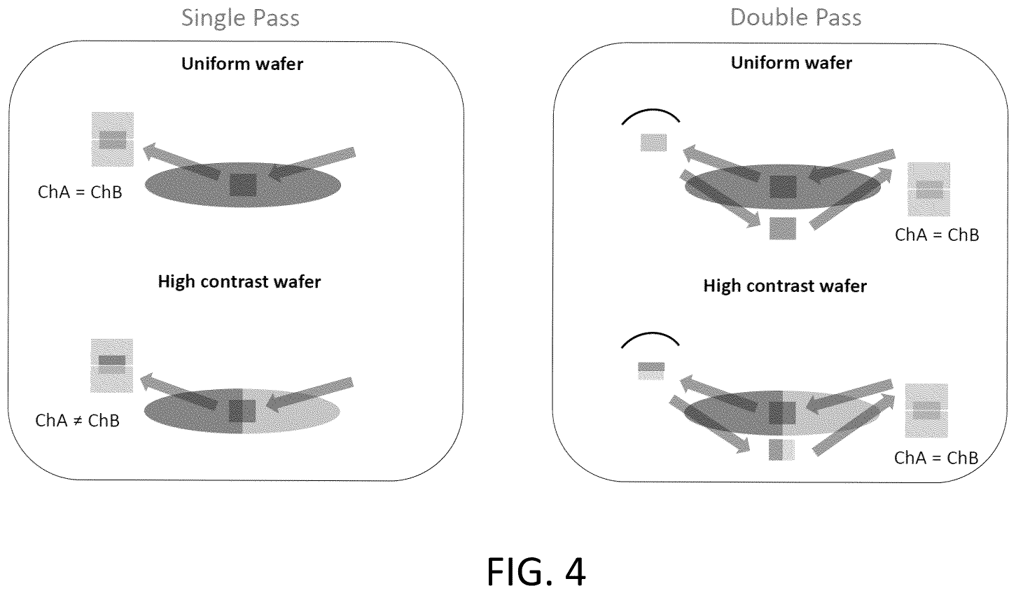

FIG. 4 illustrates a double pass using an embodiment of the system of FIG. 1 compared to a single pass. A single pass may be insufficient if the workpiece is a high contrast wafer. The system may read this as a height difference, which is incorrect because the wafer is planar. The high contrast wafer includes a brighter side on the right, which reflects more height. This problem can be avoided using a double pass, similar to what is performed in the embodiment of FIG. 1. Using the spherical mirror and two passes by the beam of light means that the images neutralize each other, which is shown in the bottom right example.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stage configured to hold a workpiece;
an electron beam column configured to direct an electron beam at the workpiece on the stage;
a light source configured to generate a light beam at the workpiece on the stage;
a sensor configured to receive the light beam reflected from the workpiece;
a mirror configured to reflect the light beam received from the workpiece toward the sensor; and
a processor in electronic communication with the sensor, wherein the processor is configured to use measurements from the sensor to determine a displacement from a nominal distance between the electron beam column and the workpiece on the stage.

2. The system of claim 1, further comprising a second mirror and a third mirror, wherein the second mirror and the third mirror are positioned in a path of the light beam, wherein the second mirror is positioned to direct the light beam from the light source at the workpiece, and wherein the third mirror is positioned to direct the light beam from the workpiece at the mirror.

3. The system of claim 2, further comprising plano-convex lenses disposed in the path of the light beam between the second mirror and the workpiece.

4. The system of claim 2, wherein the second mirror and the third mirror are each a fold mirror.

5. The system of claim 1, further comprising a beam splitter positioned in a path of the light beam between the workpiece and the light source, wherein the beam splitter directs at least some of the light beam at the sensor.

6. The system of claim 1, wherein the light source is a light-emitting diode.

7. The system of claim 1, further comprising a convex lens in a path of the light beam between the light source and the workpiece.

8. The system of claim 1, further comprising a slit in a path of the light beam between the light source and the workpiece.

9. The system of claim 1, wherein the mirror is a spherical mirror.

10. The system of claim 1, wherein the workpiece is a semiconductor wafer.

11. A method comprising:
directing a beam of light from a light source at a workpiece on a stage, wherein the workpiece is disposed an absolute distance from an electron beam column;
reflecting the beam of light off the workpiece;
receiving the beam of light reflected off the workpiece at a sensor; and
determining, using a processor, a displacement from a nominal distance between the electron beam column and the workpiece on the stage.

12. The method of claim 11, wherein the workpiece is a semiconductor wafer.

13. The method of claim 11, further comprising reflecting the beam of light reflected off the workpiece using a mirror, and wherein the reflecting the beam of light off the workpiece directs the beam of light to the mirror.

14. The method of claim 13, wherein the directing includes reflecting the beam of light off a second mirror disposed in a path of the beam of light between the light source and the workpiece.

15. The method of claim 14, wherein the reflecting the beam of light off the workpiece includes reflecting the beam of light off a third mirror disposed in the path of the beam of light between the workpiece and the mirror.

16. The method of claim 11, further comprising splitting the beam of light reflected off the workpiece using a beam splitter, wherein some of the beam of light is directed by the beam splitter to the sensor.

17. The method of claim 11, wherein the directing further includes focusing the beam of light.

18. The method of claim 11, further comprising directing the beam of light reflected off the workpiece at a same point on the workpiece a second time before the beam of light is received at the sensor.

19. The method of claim 11, further comprising adjusting a height of a stage based on the displacement from the nominal distance.
